(19) United States
(12) Patent Application Publication
(10) Pub. No.: US 2016/0365421 A1
(43) Pub. Date: Dec. 15, 2016

(54) Semiconductor Device And Manufacturing Method Thereof

(71) Applicant: TOYODA GOSEI CO., LTD., Kiyosu-shi (JP)

(72) Inventors: Kazuya HASEGAWA, Kiyosu-shi (JP); Tohru Oka, Kiyosu-shi (JP); Nariaki Tanaka, Kiyosu-shi (JP)

(21) Appl. No.: 14/611,183

(22) Filed: Jan. 31, 2015

(30) Foreign Application Priority Data
Apr. 11, 2014 (JP) 2014-082149

(51) Int. Cl. H01L 29/47; H01L 21/324; H01L 29/66; H01L 21/285; H01L 29/20; H01L 29/872

(52) U.S. Cl. CPC H01L 29/475; H01L 29/2003; H01L 29/872; H01L 29/66143; H01L 21/28581; H01L 21/324

(57) ABSTRACT

A technique of improving the barrier height between an electrode layer and a semiconductor layer is provided. A semiconductor device comprises a semiconductor layer made of a semiconductor and an electrode layer formed to be at least partly in Schottky contact with the semiconductor layer. The electrode layer includes a first layer and a second layer arranged sequentially from a semiconductor layer-side. The first layer is a layer mainly made of nickel and has a film thickness of not less than 50 nm and not greater than 200 nm. The second layer is a layer mainly made of at least one metal selected from the group consisting of palladium, platinum and iridium. The second layer has a film thickness that is equal to or greater than the film thickness of the first layer.

### CROSS-REFERENCE TO RELATED APPLICATION

The present application claims priority from Japanese patent applications No. 2014-082149 filed on Apr. 11, 2014, the entirety of disclosures of which is hereby incorporated by reference into this application.

### FIELD OF INVENTION

The invention relates to a semiconductor device.

### DESCRIPTION OF RELATED ART

GaN-based semiconductor devices including one or more semiconductor layers mainly made of gallium nitride (GaN) have been known as semiconductor devices (semiconductor elements). The GaN-based semiconductor device may function as a Schottky barrier diode (SBD) (for example, JP 2004-87587A).

Improving the barrier height between a Schottky electrode and a semiconductor layer has been demanded, in order to allow for high voltage operations in the GaN-based Schottky barrier diode. The barrier height is increased with an increase in work function of a metal used for the Schottky electrode. The metals having the large work function such as platinum (Pt) and palladium (Pd), however, have the problem of poor adhesiveness to GaN.

JP 2004-87587A discloses a manufacturing method to increase the barrier height between GaN and the Schottky electrode and improves the adhesiveness of the Schottky electrode to GaN.

FIG. 12 is a diagram illustrating a semiconductor device manufactured by the manufacturing method described in JP 2004-87587A. The manufacturing method of JP 2004-87587 includes the step of forming an electrode on a nitride semiconductor 3. The step of forming the electrode includes the step of stacking a layer of a first material 6 containing a first element on the nitride semiconductor, the step of stacking a layer of a second material 7 containing a second element 7a having a greater work function than that of the first element on the layer of the first material 6, and the step of diffusing the second element 7a into the neighborhood of an interface between the nitride semiconductor and the first material by heat treatment.

### SUMMARY OF INVENTION

The inventors have manufactured a semiconductor device by this proposed method and have found that the barrier height is rather reduced. More specifically, the inventors have found that the barrier height is reduced by diffusing the second element 7a in the neighborhood of the interface between the nitride semiconductor and the first material. Reducing the barrier height means increasing the leak current of the semiconductor device and thereby reducing the breakdown voltage of the semiconductor device.

Accordingly a different method from the above proposed method has been demanded to improve the barrier height between the semiconductor layer and the Schottky electrode. Other needs in the semiconductor device include downsizing, easy manufacture, resource saving, improvement of usability and improvement of durability.

In order to solve at least part of the problems described above, the invention may be implemented by aspects described below.

(1) According to one aspect of the invention, there is provided a semiconductor device. The semiconductor device has:a semiconductor layer made of a semiconductor; and an electrode layer formed to be at least partly in Schottky contact with the semiconductor layer, wherein the electrode layer includes a first layer and a second layer arranged sequentially from a semiconductor layer-side, the first layer is a layer mainly made of nickel and has a film thickness of not less than 50 nm and not greater than 200 nm, the second layer is a layer mainly made of at least one metal selected from the group consisting of palladium, platinum and iridium, and the second layer has a film thickness that is equal to or greater than the film thickness of the first layer. The semiconductor device of this aspect improves the barrier height between the electrode layer and the semiconductor layer.

(2) According to one embodiment of the semiconductor device of the above aspect, the first layer may include a third layer and a fourth layer arranged sequentially from the semiconductor layer-side, the third layer is a layer including less than 0.1% of the metal constituting the second layer and has a film thickness of not less than 50 nm, and the fourth layer is a layer including not less than 0.1% of the metal constituting the second layer.

(3) According to one embodiment of the semiconductor device of any of the above aspect, the semiconductor layer may be mainly made of gallium nitride.

(4) According to another aspect of the invention, there is provided a manufacturing method of a semiconductor device. The manufacturing method of a semiconductor device has: the steps of: forming an electrode layer which is at least partly in Schottky contact with a semiconductor layer; and performing heat treatment after formation of the electrode layer, wherein the step of forming the electrode layer includes a first step of forming a first layer and a second step of forming a second layer sequentially from a semiconductor layer side, the first step forms the first layer which is mainly made of nickel and has a film thickness of not less than 50 nm and not greater than 200 nm, the second step forms the second layer mainly made of at least one metal selected from the group consisting of palladium, platinum and iridium, and the second layer has a film thickness that is equal to or greater than the film thickness of the first layer.

(5) According to one embodiment, the manufacturing method of a semiconductor device of the above aspect, the heat treatment may divides the first layer into a third layer and a fourth layer sequentially from the semiconductor layer side, the third layer is a layer including less than 0.1% of the metal constituting the second layer and has a film thickness of not less than 50 nm, and the fourth layer is a layer including not less than 0.1% of the metal constituting the second layer.

(6) According to one embodiment, the manufacturing method of a semiconductor device of any of the above aspect, the heat treatment may be performed at temperature of not lower than 200° C. and not higher than 500° C. for a time of not shorter than 5 minutes and not longer than 60 minutes.

The invention may be implemented by any of various aspects other than the semiconductor device and the manufacturing method; for example, an electrical apparatus including the above semiconductor device and a manufacturing apparatus for manufacturing the above semiconductor device.

The above aspects of the invention improve the barrier height between the electrode layer and the semiconductor layer.

### BRIEF DESCRIPTION OF DRAWINGS

FIG. 1 is a cross sectional view schematically illustrating the structure of a semiconductor device according to a first embodiment;

FIG. 2 is a flowchart showing a manufacturing method of the semiconductor device according to the first embodiment;

FIG. 3 is a diagram illustrating the structure in which a semiconductor layer is formed on a substrate;

FIG. 4 is a diagram illustrating the structure in which an insulating layer is formed on the semiconductor layer;

FIG. 5 is a diagram illustrating the structure in which an opening is formed;

FIG. 6 is a diagram illustrating the structure in which a Schottky electrode is formed;

FIG. 7 is a diagram illustrating the structure in which a barrier metal layer and a wiring layer are formed;

FIG. 8 is a graph showing evaluation results of barrier height between the semiconductor layer and the Schottky electrode;

FIG. 9 is a flowchart showing a manufacturing method of a semiconductor device according to a second embodiment;

FIG. 10 is graphs showing evaluation results of barrier height between the semiconductor layer and the Schottky electrode;

FIG. 11 is diagrams illustrating the relationship of depths of Ga, Ni and Pd in the semiconductor device; and

FIG. 12 is a diagram illustrating a semiconductor device manufactured by a manufacturing method described in JP 2004-87587A.

### DESCRIPTION OF EMBODIMENTS

### A. First Embodiment

### A-1. Structure of Semiconductor Device

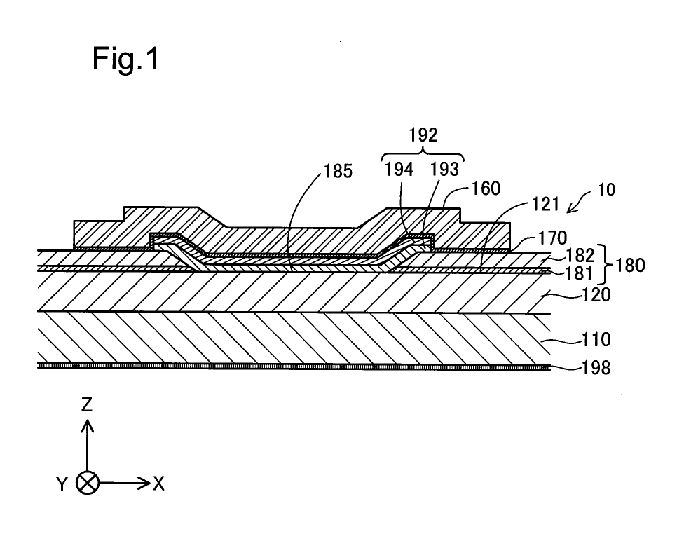

FIG. 1 is a cross sectional view schematically illustrating the structure of a semiconductor device 10 according to a first embodiment. XYZ axes orthogonal to one another are illustrated in FIG. 1.

Among the XYZ axes in FIG. 1, the X axis is an axis going from the left side of the sheet surface to the right side of the sheet surface of FIG. 1; +X-axis direction is a direction going rightward on the sheet surface and −X-axis direction is a direction going leftward on the sheet surface. Among the XYZ axes in FIG. 1, the Y axis is an axis going from the front side of the sheet surface to the rear side of the sheet surface of FIG. 1; +Y-axis direction is a direction going backward on the sheet surface and −Y-axis direction is a direction going forward on the sheet surface. Among the XYZ axes in FIG. 1, the Z axis is an axis going from the lower side of the sheet surface to the upper side of the sheet surface of FIG. 1; +Z-axis direction is a direction going upward on the sheet surface and −Z-axis direction is a direction going downward on the sheet surface.

The semiconductor device 10 is a GaN-based semiconductor device made from gallium nitride (GaN). According to this embodiment, the semiconductor device 10 is a vertical Schottky barrier diode. The semiconductor device 10 includes a substrate 110, a semiconductor layer 120, a wiring layer 160, a barrier metal layer 170, an insulating layer 180, a Schottky electrode 192 and a back side electrode 198.

The substrate 110 of the semiconductor device 10 is a plate-like semiconductor layer extended along the X axis and the Y axis. According to this embodiment, the substrate 110 is an n-type semiconductor layer which is mainly made of gallium nitride (GaN) and contains silicon (Si) as the donor. Being mainly made of gallium nitride (GaN) means containing 90% or more of gallium nitride (GaN) at the mole fraction.

The semiconductor layer 120 of the semiconductor device 10 is an n-type semiconductor layer extended along the X axis and the Y axis. According to this embodiment, the semiconductor layer 120 is mainly made of gallium nitride (GaN) and contains silicon (Si) as the donor. The semiconductor layer 120 is stacked on the +Z-axis direction side of the substrate 110. The semiconductor layer 120 has an interface 121. The interface 121 is a plane which is along the XY plane in which the semiconductor layer 120 is extended and faces the +Z-axis direction. At least part of the interface 121 may be a curved surface or may have irregularity. According to this embodiment, the semiconductor layer 120 has a film thickness of 10 μm and a donor concentration of 1×10¹⁶ cm⁻³.

The insulating layer 180 of the semiconductor device 10 has electrical insulation property and covers the interface 121 of the semiconductor layer 120. The insulating layer 180 includes a first insulating layer 181 and a second insulating layer 182.

The first insulating layer 181 of the insulating layer 180 is a layer which is made of aluminum oxide (Al₂O₃) and is adjacent to the interface 121 of the semiconductor layer 120. According to this embodiment, the first insulating layer 181 has a thickness of 100 nm. The second insulating layer 182 of the insulating layer 180 is made of silicon dioxide (SiO₂). According to this embodiment, the second insulating layer 182 has a thickness of 500 nm.

The insulating layer 180 has an opening 185 formed to pass through the first insulating layer 181 and the second insulating layer 182. The opening 185 is formed by wet etching.

The Schottky electrode 192 of the semiconductor device 10 is an electrode which has electrical conductivity and is in Schottky contact with the interface 121 of the semiconductor layer 120. According to this embodiment, the Schottky electrode 192 includes a nickel layer 193 mainly made of nickel (Ni) and a palladium layer 194 mainly made of palladium (Pd) sequentially from the semiconductor layer 120-side. In this embodiment, both the nickel layer 193 and the palladium layer 194 have film thicknesses of 100 nm. In the description herein, the Schottky electrode is an electrode having 0.5 eV or more of a difference between electron affinity of the semiconductor layer 120 and work function of the metal used for the Schottky electrode. Being mainly made of nickel (Ni) means containing 90% or more of nickel (Ni) at the molar fraction, and being mainly made of palladium (Pd) means containing 90% or more of palladium (Pd) at the molar fraction. The “Schottky electrode 192” corresponds to the “electrode layer” in Summary. Similarly the “nickel layer 193” corresponds to the “first layer”, and the “palladium layer 194” corresponds to the “second layer”. The “step of forming the nickel layer 193” corresponds to the “first step”, and the “step of forming the palladium layer 194” corresponds to the “second step”.

The nickel layer 193 has a film thickness of not less than 50 nm and not greater than 200 nm, and the palladium layer 194 has a film thickness that is equal to or greater than the film thickness of the nickel layer 193. In this embodiment, the palladium layer 194 may be replaced by a platinum layer mainly made of platinum (Pt) or may be replaced by an iridium layer mainly made of iridium (Ir). Being mainly made of platinum (Pt) means containing 90% or more of platinum (Pt) at the molar fraction, and being mainly made of iridium (Ir) means containing 90% or more of iridium (Ir) at the molar fraction.

According to this embodiment, the Schottky electrode 192 is a conductive layer provided to cover the interface 121 of the semiconductor layer 120 occupying part of the opening 185, a side face of the insulating layer 180 occupying part of the opening 185 and part of a +Z-axis direction side face of the insulating layer 180. The Schottky electrode 192 accordingly forms a field plate structure where the insulating layer 180 is placed between the semiconductor layer 120 and the Schottky electrode 192. The field plate structure is a structure connected with one or a plurality of electrode and arranged from the surface of the semiconductor layer to the surface of the insulating layer provided on the semiconductor layer so as to relieve an electric field at an end of a contact area where the electrode is in contact with the semiconductor layer. In this embodiment, the Schottky electrode is formed in the semiconductor layer and is extended to the surface of the insulating layer, so as to form the field plate structure functioning as the field plate electrode.

The barrier metal layer 170 of the semiconductor device 10 is a layer provided to suppress diffusion of the metal. The barrier metal layer 170 is formed on the Schottky electrode 192.

The barrier metal layer 170 is mainly made of molybdenum (Mo). Being mainly made of molybdenum (Mo) means containing 90% or more of molybdenum (Mo) at the molar fraction. According to this embodiment, the barrier metal layer 170 has a film thickness of 100 nm.

The wiring layer 160 of the semiconductor device 10 is an electrode layer provided on the Schottky electrode to serve as a pad electrode for forming a bonding wire or an electrode for lead wiring, for example, in the application that a Schottky barrier diode is mounted on a printed board or used as a circuit component, and is often made thick to contain a metal material having a relatively low resistivity such as Al, Au or Cu to have the smaller resistance than that of the Schottky electrode layer. The wiring layer 160 of the semiconductor device 10 is formed on the barrier metal layer 170. The wiring layer 160 is a layer for connecting the semiconductor device 10 with the wiring connected with another semiconductor device. The wiring layer 160 is a layer mainly made of aluminum (Al). Being mainly made of aluminum (Al) means containing 90% or more of aluminum (Al) at the molar fraction. According to this embodiment, the wiring layer 160 is made of aluminum silicon (AlSi) which includes 1% of silicon (Si) added to aluminum (Al). In this embodiment, the wiring layer 160 has a film thickness of 4 μm. The wiring layer 160, the barrier metal layer 170 and the Schottky electrode 192 serve as an anode electrode of the Schottky barrier diode.

The back side electrode 198 of the semiconductor device 10 is an electrode which is in ohmic contact with the −Z axis direction side of the substrate 110. According to this embodiment, the back side electrode 198 is an electrode alloyed by heat treatment of a stacked structure of a layer made of aluminum silicon (AlSi) stacked on a layer made of titanium (Ti) (where Ti is located on the substrate side).

### A-2. Manufacturing Method of Semiconductor Device

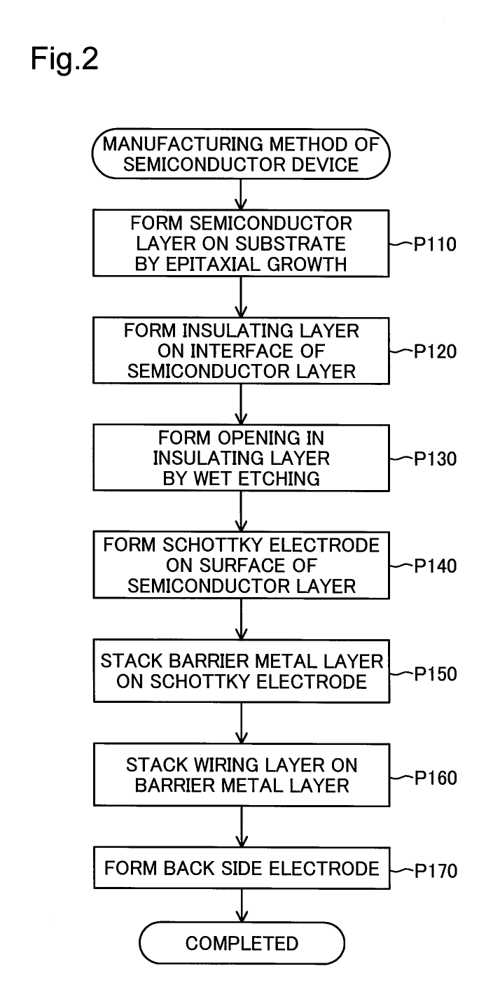

FIG. 2 is a flowchart showing a manufacturing method of the semiconductor device 10. In the process of manufacturing the semiconductor device 10, the manufacturer forms the semiconductor layer 120 on the substrate 110 by epitaxial growth at step P110.

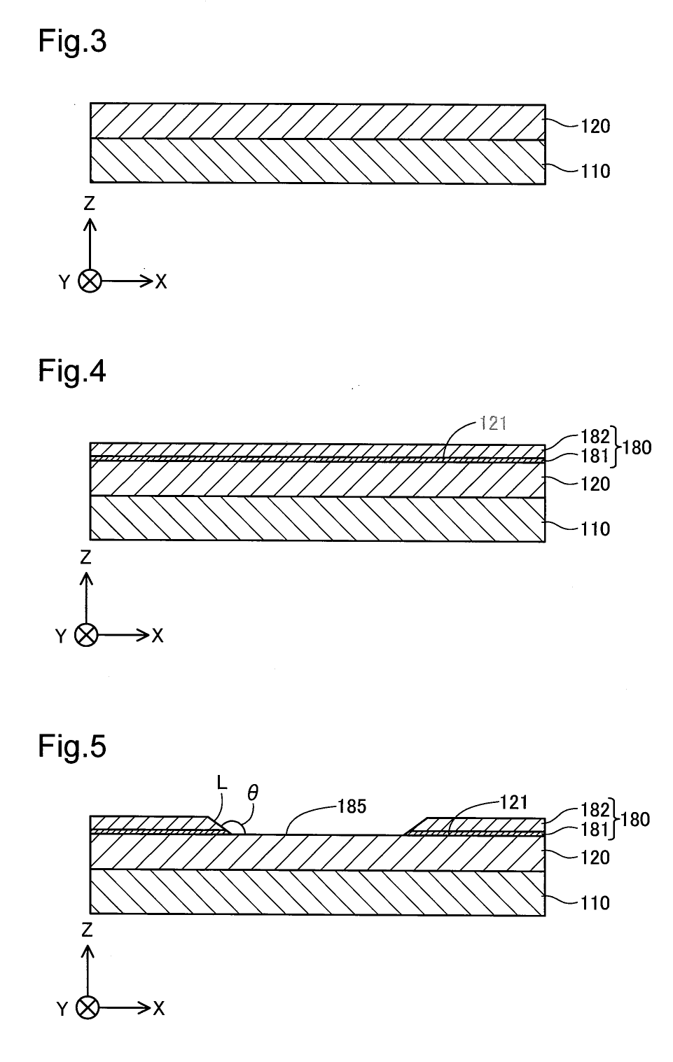

FIG. 3 is a diagram illustrating the structure in which the semiconductor layer 120 is formed on the substrate 110. According to this embodiment, the manufacturer forms the semiconductor layer 120 on the substrate 110 by epitaxial growth using an MOCVD device performing MOCVD (metal organic chemical vapor deposition).

After forming the semiconductor layer 120 (step P110), the manufacturer forms the insulating layer 180 on the interface 121 of the semiconductor layer 120 at step P120.

FIG. 4 is a diagram illustrating the structure in which the insulating layer 180 is formed on the semiconductor layer 120.

The manufacturer first forms the first insulating layer 181 made of aluminum oxide (Al₂O₃) as the insulating layer 180 on the interface 121 of the semiconductor layer 120. According to this embodiment, the manufacturer forms the first insulating layer 181 by ALD (atomic layer deposition) method.

The manufacturer subsequently forms the second insulating layer 182. The second insulating layer 182 is made of silicon dioxide (SiO₂). According to this embodiment, the manufacturer forms the second insulating layer 182 by CVD (chemical vapor deposition) method.

After forming the insulating layer 180 (step P120), the manufacturer forms the opening 185 in the insulating layer 180 by wet etching at step P130. According to this embodiment, the manufacturer forms a mask on the insulating layer 180 by photolithography and removes part of the insulating layer 180 by wet etching to form the opening 185.

FIG. 5 is a diagram illustrating the structure in which the opening 185 is formed. According to this embodiment, a side wall L of the insulating layer 180 which forms a side face of the opening 185 is inclined to have an angle θ (90 degrees <θ<180 degrees) with respect to the semiconductor layer 120 in terms of reliving the electric field. The angle θ is preferably not less than 100 degrees and not greater than 170 degrees. The side wall L of the insulating layer 180 may be perpendicular to the semiconductor layer 120 (θ=90 degrees).

After forming the opening 185 (step P130), the manufacturer first forms the nickel layer 193 and subsequently forms the palladium layer 194 as the Schottky electrode 192 on the interface of the semiconductor layer 120 exposed on the opening 185 of the insulating layer 180 at step P140.

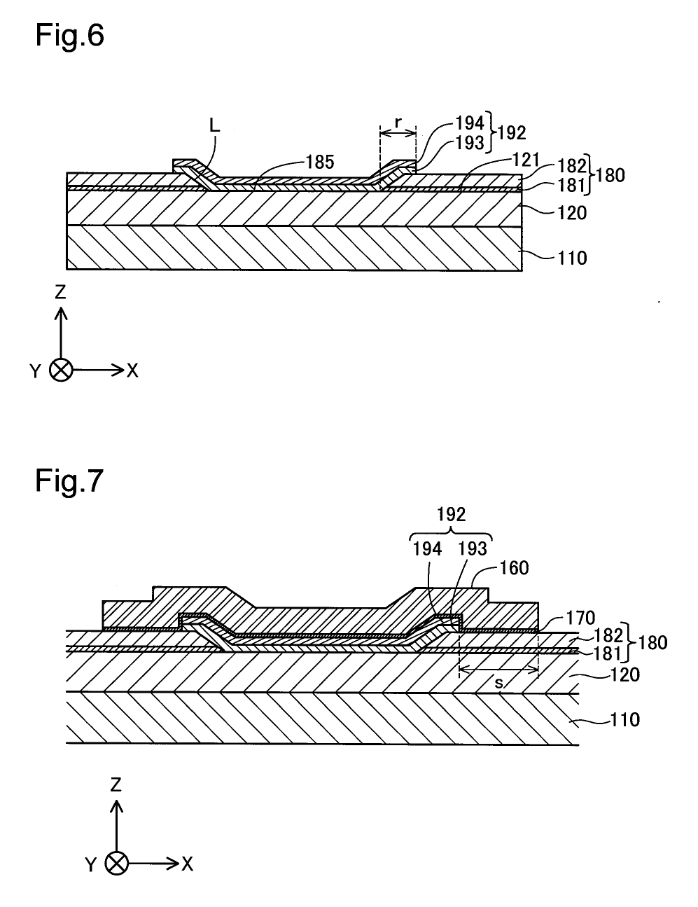

FIG. 6 is a diagram illustrating the structure in which the Schottky electrode 192 is formed. According to this embodiment, the manufacturer forms the Schottky electrode 192 by lift-off method. More specifically, the manufacturer forms a mask on an area of the insulating layer 180 other than a part where the Schottky electrode 192 is formed by photolithography, causes the nickel layer 193 and the palladium layer 194 to deposit by electron beam (EB) in this sequence on the insulating layer 180 and the opening 185 and subsequently removes the mask from the insulating layer 180 with leaving the Schottky electrode 192. According to this embodiment, the Schottky electrode 192 is formed to cover the interface 121 of the semiconductor layer 120 occupying part of the opening 185, the side wall L of the insulating layer 180 occupying part of the opening 185 and part of the +Z-axis direction side face of the insulating layer 180.

A distance r between an end of the Schottky electrode 192 and an opening end of the opening 185 is shown in FIG. 6. In terms of sufficiently providing the effect of reliving the electric field by the field plate structure and suppressing deterioration of the properties of the semiconductor device 10 as the element caused by diffusion of the subsequently formed barrier metal layer 170 and wiring layer 160 into the semiconductor layer 120, the lower limit of the distance r is preferably not less than 2 μm, is more preferably not less than 5 μm and is furthermore preferably not less than 10 μm. The excessively long distance r, on the other hand, expands the size of the semiconductor device 10 and increases the manufacturing cost. The upper limit of the distance r is thus preferably not greater than 1 mm. In this embodiment, the distance r is set to 10 μm.

After forming the Schottky electrode 192 (step P140), the manufacture stacks the barrier metal layer 170 on the Schottky electrode 192 by sputtering method at step P150. The barrier metal layer 170 is made of molybdenum (Mo). The material of the barrier metal layer is, however, not limited to molybdenum (Mo) but may be another material such as vanadium (V), titanium (Ti) or titanium nitride (TiN). In other words, the barrier metal layer may contain at least one metal or metal compound selected from the group consisting of molybdenum, vanadium, titanium and titanium nitride or its alloy. The barrier metal layer is not limited to a single layer but may be a multi-layered structure of, for example, titanium nitride (TiN)/titanium (Ti) (where the denominator is the Schottky electrode side: the same applies hereafter in this paragraph), titanium (Ti)/titanium nitride (TiN), molybdenum (Mo)/vanadium (V), vanadium (V)/molybdenum (Mo), or titanium (Ti)/titanium nitride (TiN)/titanium (Ti).

After stacking the barrier metal layer 170 (step P150), the manufacturer further stacks the wiring layer 160 at step P160. The wiring layer 160 is also stacked by the sputtering method. According to this embodiment, the wiring layer 160 is made of aluminum silicon (AlSi). The material of the wiring layer is, however, not limited to aluminum silicon (AlSi) but may be aluminum (Al), aluminum copper (AlCu) or aluminum silicon copper (AlSiCu) mainly made of aluminum (Al) or a material other than aluminum (Al), such as gold (Au) or copper (Cu). The wiring layer is not limited to the single layer but may be a multi-layered structure.

In the embodiment, the wiring layer 160 is formed sequentially after formation of the barrier metal layer 170. More specifically, the layer of molybdenum (Mo) and the layer of aluminum silicon (AlSi) are sequentially formed by the sputtering method.

After stacking the barrier metal layer 170 and the wiring layer 160 by the sputtering method, the method forms a mask pattern by a photoresist. The mask pattern is formed to cover the entire Schottky electrode 192 formed at step P140. The method subsequently removes an area other than a part covered by the photo resist by chlorine-based dry etching to form the barrier metal layer 170 and the wiring layer 160. The technique of deposition by EB (electron beam) may be employed instead of the sputtering method to form the barrier metal layer 170 and the wiring layer 160. Another technique without etching may also be employed: for example, a method of forming a mask pattern by a photoresist and subsequently stacking an electrode material to form the layers by the lift-off method.

FIG. 7 is a diagram illustrating the structure in which the barrier metal layer 170 and the wiring layer 160 are formed. A distance s between an end of the Schottky electrode 192 and an end of the wiring layer 160 is shown in FIG. 7. In terms of sufficiently suppressing peel-off of the Schottky electrode 192 from the insulating layer 180, the lower limit of the distance s is preferably not less than 3 μm, is more preferably not less than 5 μm and is furthermore preferably not less than 10 μm. The excessively long distance s, on the other hand, expands the size of the semiconductor device 10 and increases the manufacturing cost. The upper limit of the distance s is thus preferably not greater than 1 mm. In this embodiment, the distance s is set to 10 μm.

After forming the wiring layer 160 (step P160), the manufacturer forms the back side electrode 198 on the −Z axis direction side of the substrate 110 at step P170. According to this embodiment, the manufacturer forms a layer made of titanium (Ti) by deposition on the −Z axis direction side of the substrate 110, subsequently forms a layer made of aluminum silicon (AlSi) by deposition on the titanium layer and alloys these layers by heat treatment, so as to form the back side electrode 198. The heat treatment reduces the contact resistance of the back side electrode 198. According to this embodiment, the heat treatment is performed in a nitrogen atmosphere at 400° C. for 30 minutes. The sputtering method may be employed for formation of the back side electrode.

The semiconductor device 10 is completed through this sequence of steps. According to this embodiment, the Schottky electrode 192 includes the nickel layer 193 and the palladium layer 194. The nickel layer 193 and the palladium layer 194 respectively have film thicknesses of 100 nm.

### A-3. Evaluation of Barrier Height Between Semiconductor Layer and Schottky Electrode

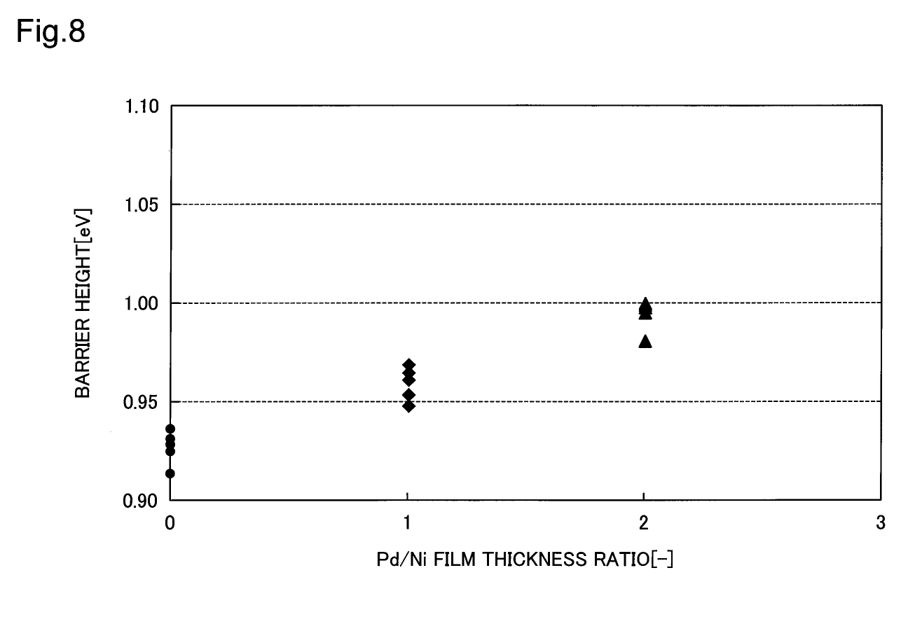

FIG. 8 is a graph showing evaluation results of barrier height between the semiconductor layer and the Schottky electrode. In the evaluation test of FIG. 8, a plurality of test samples were provided as semiconductor devices, and the barrier height between the semiconductor layer and the Schottky electrode was measured.

Test sample 1 was a semiconductor device manufactured by stacking a nickel layer of 100 nm on the semiconductor layer 120. Test sample 2 was a semiconductor device manufactured by stacking a nickel layer of 100 nm on the semiconductor layer 120 and subsequently stacking a palladium layer of 100 nm. Test sample 3 was a semiconductor device manufactured by stacking a nickel layer of 50 nm on the semiconductor layer 120 and subsequently stacking a palladium layer of 100 nm.

FIG. 8 shows the results of Test samples 1 to 3 as the results of Pd/Ni film thickness ratio of 0 to 2. According to these results, the semiconductor devices including the palladium layer of the film thickness equal to or greater than the film thickness of the nickel layer (Test samples 2 and 3) have improved barrier height compared with the semiconductor device without the palladium layer (Test sample 1). Test sample 3 has further improvement in barrier height compared with Test sample 2. As shown in these results, application of the invention improves the barrier height.

With respect to the relationship of the film thickness between the palladium layer and the nickel layer, it is preferable that the film thickness of the palladium layer is equal to or greater than the film thickness of the nickel layer, in order to ensure the sufficient effect of improving the barrier height. In terms of reducing the manufacturing cost and shortening the manufacturing time, the Pd/Ni film thickness ratio is preferably not greater than 100.

With respect to the film thickness of the nickel layer, the excessively large film thickness of the nickel layer has little effect of improving the barrier height and has no significant difference from the nickel single layered structure. Accordingly, the film thickness of the nickel layer is preferably not greater than 500 nm and is more preferably not greater than 200 nm.

### B. Second Embodiment

### B-1. Manufacturing Method of Semiconductor Device

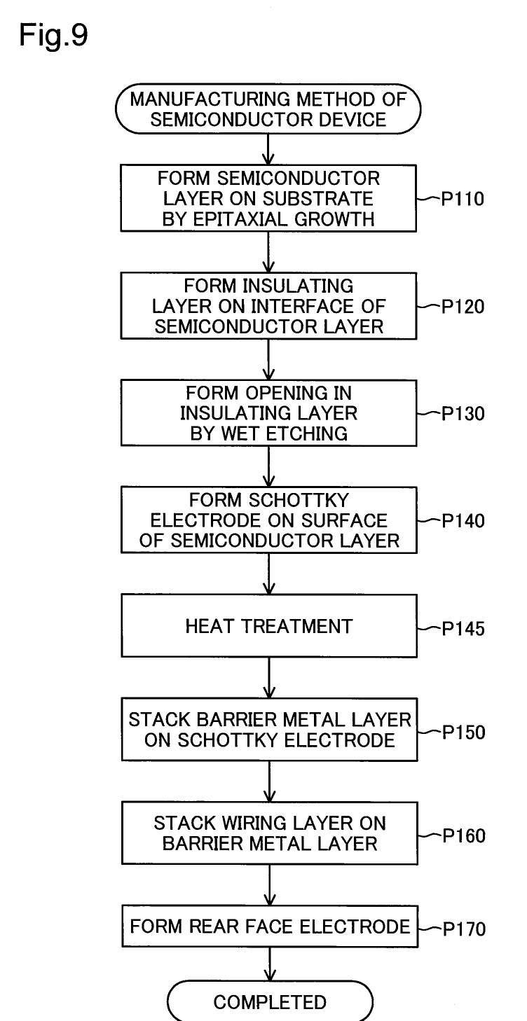

FIG. 9 is a flowchart showing another manufacturing method of the semiconductor device 10 according to a second embodiment. The manufacturing method of this embodiment performs heat treatment at step P145 after formation of the Schottky electrode 192 (step P140) in the manufacturing method of the first embodiment. The heat treatment after formation of the Schottky electrode 192 divides the nickel layer 193 into (i) a layer containing palladium of less than 0.1% and having a film thickness of not less than 50 nm and (ii) a layer containing palladium of not less than 0.1% sequentially from the semiconductor layer 120-side. The layer containing palladium of less than 0.1% corresponds to the “third layer” in Summary, and the layer containing palladium of not less than 0.1% corresponds to the “fourth layer” in Summary.

### B-2. Evaluation of Barrier Height Between Semiconductor Layer and Schottky Electrode Before and after Heat Treatment

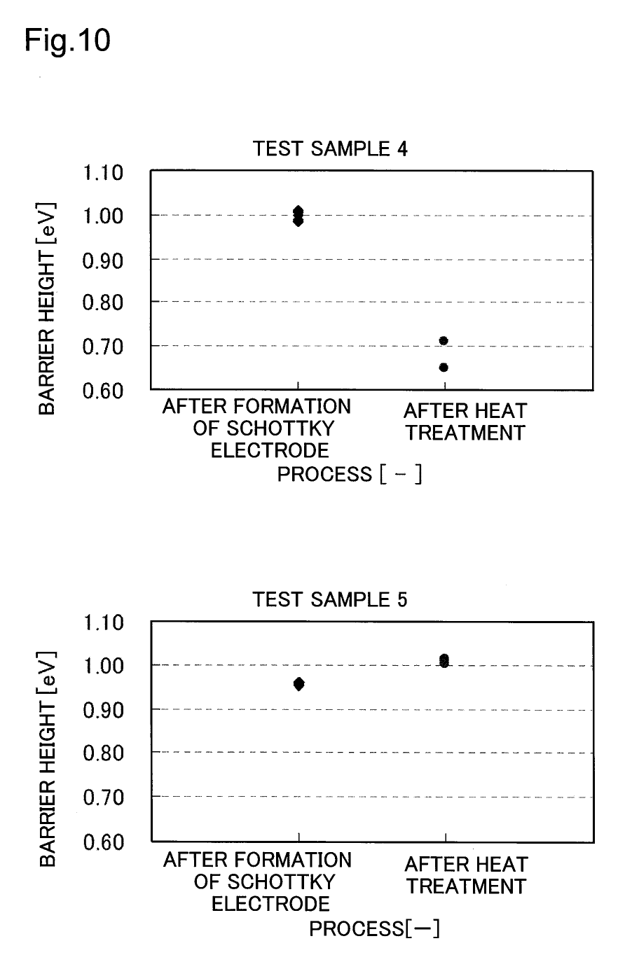

FIG. 10 is graphs showing evaluation results of barrier height between the semiconductor layer and the Schottky electrode. In the evaluation test of FIG. 10, a plurality of test samples were provided as semiconductor devices, and the barrier height between the semiconductor layer and the Schottky electrode was measured in the respective Test samples before and after heat treatment (step P145). Test sample 4 was a semiconductor device manufactured by stacking a nickel layer of 50 nm on the semiconductor layer 120 and subsequently stacking a palladium layer of 100 nm and was subjected to heat treatment in a nitrogen atmosphere at 550° C. for 10 minutes. Test sample 5 was a semiconductor device manufactured by stacking a nickel layer of 100 nm on the semiconductor layer 120 and subsequently stacking a palladium layer of 100 nm and was subjected to heat treatment in a nitrogen atmosphere at 400° C. for 30 minutes. The upper graph shows the results of Test sample 4, and the lower graph shows the results of Test sample 5.

According to the results of FIG. 10, Test sample 4 has the reduced barrier height by heat treatment after formation of the Schottky electrode, while Test sample 5 has the improved barrier height by heat treatment after formation of the Schottky electrode.

### B-3. Evaluation of Diffusion of Metal

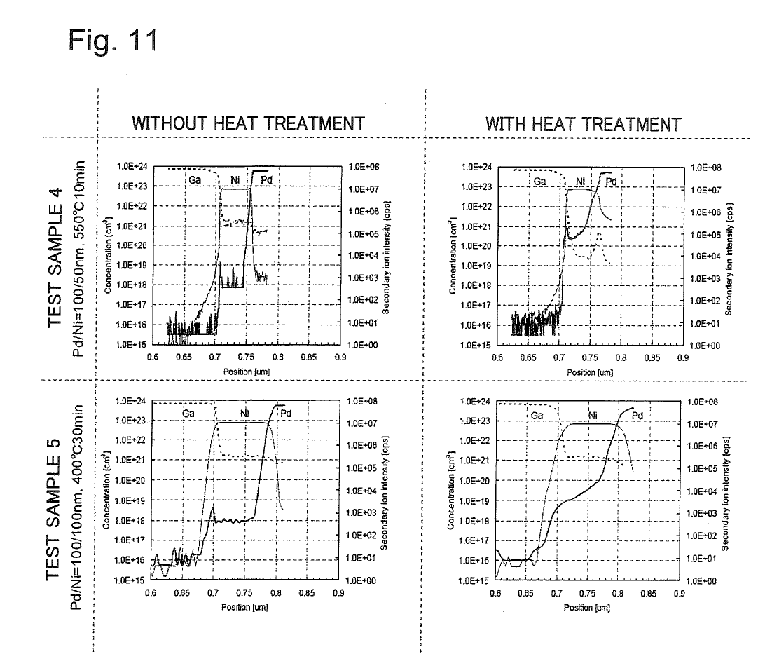

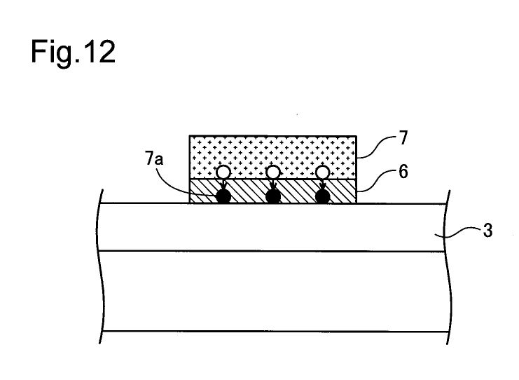

FIG. 11 shows the relationship of the depth of Ga, Ni and P in the semiconductor devices of Test sample 4 (nickel layer: 50 nm, palladium layer: 100 nm, heat treatment: 550° C. for 10 minutes) and Test sample 5 (nickel layer: 100 nm, palladium layer: 100 nm, heat treatment: 400° C. for 30 minutes) subjected to heat treatment (with heat treatment) and not subjected to heat treatment (without heat treatment). The ordinate shows the concentrations of nickel and palladium (left axis) and the count number of gallium (right axis). The abscissa shows the depth in the semiconductor device. On the abscissa, 0.6 μm side denotes the semiconductor layer side, and 0.9 μm side denotes the palladium layer side. The upper graphs show the results of Test sample 4, and the lower graphs show the results of Test sample 5. The left graphs show the results without heat treatment, and the right graphs show the results with heat treatment.

According to the results of both Test sample 4 and Test sample 5 shown in FIG. 11, heat treatment has caused palladium to be diffused toward the semiconductor layer side (leftward in the drawing) and increased the palladium concentration in the nickel layer. Test sample 4 has the palladium concentration of not lower than 1.0×10²⁰ cm⁻³ in the nickel layer having the nickel concentration of about 1.0×10²³ cm⁻³, and Test sample 5 has a layer having the palladium concentration of lower than 1.0×10²⁰ cm⁻³ in the thickness of not less than 50 nm from the semiconductor layer side in the nickel layer having the nickel concentration of about 1.0×10²³ cm⁻³. In other words, the results of Test sample 4 show that the entire nickel layer forms the layer containing not less than 0.1% of palladium after heat treatment, whereas the results of Test sample 5 show that the layer of not less than 50 nm from the semiconductor layer side in the nickel layer forms the layer containing less than 0.1% of palladium after heat treatment.

As shown in FIGS. 10 and 11, the presence of the layer having the palladium concentration of not lower than 1.0×10²⁰ cm⁻³ on the semiconductor layer side in the nickel layer reduces the barrier height, while the presence of the layer having the palladium concentration of lower than 1.0×10²⁰ cm⁻³ in the thickness of not less than 50 nm from the semiconductor layer side in the nickel layer improves the barrier height. Accordingly, thickening the film thickness of the nickel layer and lowering the heat treatment temperature to diffuse palladium toward the semiconductor layer side and form the layer having the palladium concentration of less than 0.1% on the semiconductor layer side in the nickel layer improves the barrier height between the semiconductor layer 120 and the Schottky electrode 192.

The conditions of heat treatment have been studied: more specifically, the conditions of heat treatment for improving the barrier height by diffusion of palladium toward the semiconductor layer side and the presence of the layer having the palladium concentration of lower than 1.0×10²⁰ cm⁻³ in the thickness of not less than 50 nm from the semiconductor layer side in the nickel layer. The results of the study show that the heat treatment temperature of not lower than 200° C. and not higher than 500° C. and the heat treatment time of not shorter than 5 minutes and not longer than 60 minutes improve the barrier height between the Schottky electrode and the semiconductor layer.

The nickel layer is required to include the layer having the palladium concentration of less than 1.0×10²⁰ cm⁻³ in the thickness of not less than 50 nm from the semiconductor layer side. The film thickness of the nickel layer is thus preferably not less than 50 nm.

### C. Other Embodiments

The invention is not limited to any of the embodiments, the examples and the modifications described herein but may be implemented by a diversity of other configurations without departing from the scope of the invention. For example, the technical features of the embodiments, examples or modifications corresponding to the technical features of the respective aspects described in Summary may be replaced or combined appropriately, in order to solve part or all of the problems described above or in order to achieve part or all of the advantageous effects described above. Any of the technical features may be omitted appropriately unless the technical feature is described as essential herein.

In the above embodiment, the Schottky barrier diode is used as the semiconductor device. The invention is, however, not limited to this embodiment but is also applicable to a semiconductor device having a Schottky electrode, for example, MESFET (Metal Semiconductor Field Effect Transistor) or HFET (hetero FET). In other words, the invention is applicable to a semiconductor device including a semiconductor layer and a Schottky electrode.

In the above embodiments, the technique of forming the respective layers of the insulating layer is not limited to the ALD method or the CVD method but may be the sputtering method or the application method.

The method of forming the Schottky electrode, the barrier metal layer and the wiring layer described in the above embodiment first forms the Schottky electrode and then sequentially forms the barrier metal layer and the wiring layer. This method is, however, not essential. Another applicable method may sequentially form a Schottky electrode and a barrier metal layer and subsequently form a wiring layer or subsequently form another barrier metal layer and a wiring layer. Another applicable method may individually form a Schottky electrode, a barrier metal layer and a wiring layer.

The semiconductor device includes the barrier metal layer in the above embodiment, but may not include the barrier metal layer. The wiring layer may be a single layer of aluminum (Al) or gold (Au) or may be a multi-layered structure including the barrier metal layer.

In the above embodiment, the insulating layer has the multi-layered structure of silicon oxide (SiO₂)/aluminum oxide (Al₂O₃). The insulating layer is, however, not limited to this structure but may be a single layer or any suitable multi-layered structure other than the above. The insulating layer may be made of, for example, silicon oxide (SiO₂), silicon nitride (SiN), aluminum oxide (Al₂O₃), aluminum oxynitride (AlON), zirconium oxide (ZrO₂), zirconium oxynitride (ZrON), silicon oxynitride (SiON) or hafnium oxide (HfO₂).

In the above embodiment, the material of the substrate is not limited to gallium nitride (GaN) but may be, for example, silicon (Si), sapphire (Al₂O₃) or silicon carbide (SiC).

In the above embodiment, the donor included in the n-type semiconductor layer is not limited to silicon (Si) but may be another element such as germanium (Ge) or oxygen (O).

In the above embodiment, the material of the back side electrode is not limited to the alloy of titanium (Ti) and aluminum silicon (AlSi) but may be another metal such as aluminum (Al), vanadium (V) or hafnium (Hf).

1. A semiconductor device, comprising:
a semiconductor layer made of a semiconductor; and
an electrode layer formed to be at least partly in Schottky contact with the semiconductor layer, wherein
the electrode layer includes a first layer and a second layer arranged sequentially from a semiconductor layer-side,
the first layer is a layer mainly made of nickel and has a film thickness of not less than 50 nm and not greater than 200 nm,
the second layer is a layer mainly made of at least one metal selected from the group consisting of palladium, platinum and iridium, and
the second layer has a film thickness that is equal to or greater than the film thickness of the first layer.

2. The semiconductor device according to claim 1,
wherein the first layer includes a third layer and a fourth layer arranged sequentially from the semiconductor layer-side,
the third layer is a layer including less than 0.1% of the metal constituting the second layer and has a film thickness of not less than 50 nm, and
the fourth layer is a layer including not less than 0.1% of the metal constituting the second layer.

3. The semiconductor device according to claim 1,
wherein the semiconductor layer is mainly made of gallium nitride.

4. A manufacturing method of a semiconductor device, comprising the steps of:
forming an electrode layer which is at least partly in Schottky contact with a semiconductor layer; and
performing heat treatment after formation of the electrode layer, wherein
the step of forming the electrode layer includes a first step of forming a first layer and a second step of forming a second layer sequentially from a semiconductor layer side,
the first step forms the first layer which is mainly made of nickel and has a film thickness of not less than 50 nm and not greater than 200 nm,
the second step forms the second layer mainly made of at least one metal selected from the group consisting of palladium, platinum and iridium, and
the second layer has a film thickness that is equal to or greater than the film thickness of the first layer.

5. The manufacturing method of the semiconductor device according to claim 4,
wherein the heat treatment divides the first layer into a third layer and a fourth layer sequentially from the semiconductor layer side,
the third layer is a layer including less than 0.1% of the metal constituting the second layer and has a film thickness of not less than 50 nm, and
the fourth layer is a layer including not less than 0.1% of the metal constituting the second layer.

6. The manufacturing method of the semiconductor device according to claim 4,
wherein the heat treatment is performed at temperature of not lower than 200° C. and not higher than 500° C. for a time of not shorter than 5 minutes and not longer than 60 minutes.
